(19) United States
(12) Patent Application Publication
(10) Pub. No.: US 2024/0036089 A1
(43) Pub. Date: Feb. 1, 2024

(54) METHOD AND APPARATUS FOR ADJUSTING QUBIT FREQUENCY, ELECTRONIC DEVICE AND READABLE STORAGE MEDIUM

(71) Applicant: Beijing Baidu Netcom Science Technology Co., Ltd., Beijing (CN)

(72) Inventors: Li LI, Beijing (CN); Xueyi GUO, Beijing (CN)

(21) Appl. No.: 18/483,197

(22) Filed: Oct. 9, 2023

(30) Foreign Application Priority Data
Mar. 31, 2023 (CN) 202310341847.5

(51) Int. Cl. G01R 23/00; G06N 10/40

(52) U.S. Cl. CPC G01R 23/005; G06N 10/40

(57) ABSTRACT

The present disclosure provides a method and apparatus for adjusting a qubit frequency, an electronic device and a readable storage medium. For at least two frequency-adjustable qubits in a multi-bit quantum chip, a corresponding upper-limit/lower-limit setting parameter is determined through an upper-limit frequency and a lower-limit frequency centered by a target frequency and in combination with a fitting corresponding relationship, thus determining a rate between a change of a frequency and a change of a setting parameter. After the target setting parameter is set for each qubit, the parameter for another qubit directly coupled to the qubit is adjusted to the upper-limit setting parameter and the lower-limit setting parameter, and then the actual frequency of a current qubit is determined according to a current upper-limit frequency and a current lower-limit frequency.

### CROSS-REFERENCE TO RELATED APPLICATIONS

The present application claims the priority of Chinese Patent Application No. 202310341847.5, titled “METHOD AND APPARATUS FOR ADJUSTING QUBIT FREQUENCY, ELECTRONIC DEVICE AND READABLE STORAGE MEDIUM”, filed on Mar. 31, 2023, the content of which is incorporated herein by reference in its entirety.

### TECHNICAL FIELD

The present disclosure relates to the field of quantum chip technology, specifically to the fields of qubit, frequency adjustment, resonance, quantum walk and quantum entanglement technologies, and particularly to a method and apparatus for adjusting a qubit frequency, an electronic device, a computer readable storage medium and a computer program product.

### BACKGROUND

High-precision quantum chip adjustment and control is the basis of quantum computing and quantum simulation. During the quantum simulation, it is often required to regulate some or all frequency-adjustable qubits in a multi-bit quantum chip to be resonant or nearly resonant, to cause these qubits to simulate a global entanglement and so on through interactions.

In such a condition, superconducting quantum chips may be used for simulations of a quantum walk, an optical lattice, a Bose-Hubbard model, etc.

### SUMMARY

Embodiments of the present disclosure provide a method for adjusting a qubit frequency, an electronic device, and a computer readable storage medium.

In a first aspect, a method for adjusting a qubit frequency is provided according to embodiments of the disclosure, which includes: determining, according to fitting corresponding relationships between frequencies of at least two frequency-adjustable qubits in a multi-bit quantum chip and setting parameters, respective target setting parameters of the qubits at a target frequency, and a corresponding upper-limit setting parameter and a corresponding lower-limit setting parameter of each of the qubits at a frequency range using the target frequency as a center and a preset frequency as a variation limit; adjusting, for each qubit, a setting parameter for another qubit having a direct coupling relationship with the each qubit to a corresponding upper-limit setting parameter and a corresponding lower-limit setting parameter respectively to obtain a current upper-limit frequency and a current lower-limit frequency of the each qubit, after setting respectively setting parameters of a frequency regulator for the qubits to corresponding target setting parameters; calculating a suspected frequency of a corresponding qubit according to the current upper-limit frequency and the current lower-limit frequency;

updating, in response to a frequency difference between the suspected frequency and a target frequency of the corresponding qubit being greater than a preset frequency difference, the target setting parameter according to a rate of change between a frequency and a setting parameter until a frequency difference between an actual frequency corresponding to an updated setting parameter and the target frequency of the corresponding qubit is not greater than the preset frequency difference, the rate of change being determined from the fitting corresponding relationship; and determining that each qubit is in a resonance or near-resonance state, in response to a frequency difference between a suspected frequency and an updated frequency of the each qubit being smaller than the preset frequency difference.

In a second aspect, an electronic device is provided according to embodiments of the disclosure, which includes: at least one processor; a memory in communication with the at least one processor, wherein the memory stores instructions executable by the at least one processor, and the instructions are executed by the at least one processor, to enable the at least one processor to perform the method for adjusting a qubit frequency according to the first aspect.

In a third aspect, a non-transitory computer readable storage medium storing one or more computer instructions is provided according to embodiments of the disclosure, where the one or more computer instructions are used to cause a computer to perform the method for adjusting a qubit frequency according to the first aspect.

It should be understood that the content described in this part is not intended to identify key or important features of the embodiments of the present disclosure, and is not used to limit the scope of the present disclosure. Other features of the present disclosure will be easily understood through the following description.

### BRIEF DESCRIPTION OF THE DRAWINGS

After reading detailed descriptions of non-limiting embodiments given with reference to the following accompanying drawings, other features, objectives and advantages of the present disclosure will be more apparent:

FIG. 1 is a diagram of an example system architecture in which the present disclosure may be applied;

FIG. 2 is a flowchart of a method for adjusting a qubit frequency according to an embodiment of the present disclosure;

FIG. 3 is a flowchart of a method for updating a setting parameter according to a rate of change according to an embodiment of the present disclosure;

FIG. 4 is a structural block diagram of an apparatus for adjusting a qubit frequency according to an embodiment of the present disclosure; and

FIG. 5 is a schematic structural diagram of an electronic device adapted to perform the method for adjusting a qubit frequency according to an embodiment of the present disclosure.

### DETAILED DESCRIPTION OF EMBODIMENTS

Example embodiments of the present disclosure are described below in combination with the accompanying drawings, and various details of the embodiments of the present disclosure are included in the description to facilitate understanding, and should be considered as an example only. Accordingly, it should be recognized by one of ordinary skill in the art that various changes and modifications may be made to the embodiments described herein without departing from the scope and spirit of the present disclosure. Also, for clarity and conciseness, descriptions for well-known functions and structures are omitted in the following description. It should be noted that the embodiments in the present disclosure and the features in the embodiments may be combined with each other on a non-conflict basis.

In the technical solution of the present disclosure, the collection, storage, use, processing, transmission, provision, disclosure, etc. of the personal information of a user all comply with the provisions of the relevant laws and regulations, and do not violate public order and good customs.

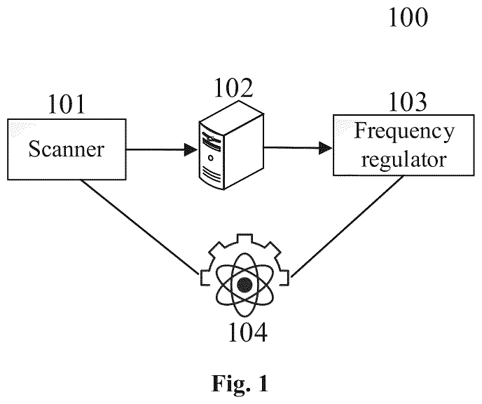

FIG. 1 illustrates an example system architecture 100 in which embodiments of a method and apparatus for adjusting a qubit frequency, an electronic device and a computer readable storage medium according to the present disclosure may be applied.

As shown in FIG. 1, the system architecture 100 may include a scanner 101, a computing and control terminal 102, a frequency regulator 103 and a multi-bit quantum chip 104. Here, the scanner 101 is configured to scan the frequencies of at least two frequency-adjustable qubits in the multi-bit quantum chip 104 and corresponding setting parameters of the frequency regulator 103, to determine the corresponding relationship therebetween. The computing and control terminal 102 is configured to calculate a more accurate setting parameter according to the corresponding relationship, and configured to control the frequency regulator 103 to perform a setting parameter adjustment such that through the parameter adjustment, the qubits can be in a resonance or near-resonance state.

The scanner 101, the computing and control terminal 102 and the frequency regulator 103 may exchange information through a pre-established data transmission path to receive or transmit a message, or the like. On the scanner 101, the computing and control terminal 102 and the frequency regulator 103, various applications (e.g., a parameter scanning application, a data analysis application, and a regulation and control application) for implementing information communication therebetween may be installed.

The computing and control terminal 102 can provide various services through various built-in applications. A regulation and control application that can provide a frequency regulation service is taken as an example. When running the regulation and control application, the computing and control terminal 102 can achieve the following effects. First, according to a fitting corresponding relationship between frequencies of qubits in the multi-bit quantum chip 104 and setting parameters, target setting parameters of the qubits at a target frequency, and a corresponding upper-limit setting parameter and a corresponding lower-limit setting parameter of each of the qubits at a frequency range using the target frequency as a center and a preset frequency as a variation limit. Then, after the setting parameters of the frequency regulator for the qubits are respectively set to corresponding target setting parameters, for each qubit, a setting parameter for another qubit having a direct coupling relationship the qubit is respectively adjusted to a corresponding upper-limit setting parameter and a lower-limit setting parameter to obtain a current upper-limit frequency and a current lower-limit frequency of the qubit. Next, a suspected frequency of a corresponding qubit is calculated according to the current upper-limit frequency and the current lower-limit frequency. Next, when a frequency difference between the suspected frequency and a target frequency of the corresponding qubit is greater than a preset frequency difference, the target setting parameter is updated according to a rate of change between a frequency and a setting parameter that is determined from the fitting corresponding relationship, until a frequency difference between an actual frequency corresponding to an updated setting parameter and the target frequency of the corresponding qubit is not greater than the preset frequency difference. Finally, when a frequency difference between a suspected frequency and an updated frequency of each qubit being smaller than the preset frequency difference, it is determined that each qubit is in a resonance or near-resonance state.

The method for adjusting a qubit frequency according to the subsequent embodiments of the present disclosure is generally performed by the computing and control terminal 102, and correspondingly, the apparatus for adjusting a qubit frequency is generally arranged in the computing and control terminal 102.

It should be appreciated that the numbers of the scanners, the computing and control terminals, the frequency regulators and the multi-bit quantum chips in FIG. 1 are merely illustrative. Any number of scanners, computing and control terminals, frequency regulators and multi-bit quantum chips may be provided based on actual requirements.

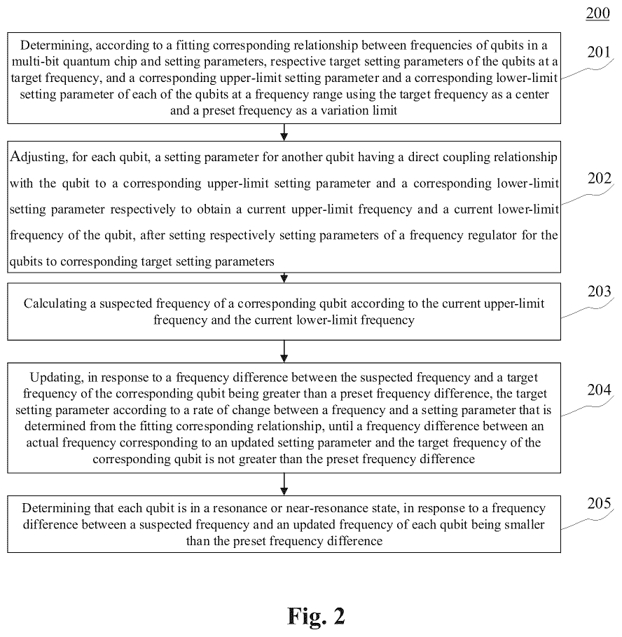

Referring to FIG. 2, FIG. 2 is a flowchart of a method for adjusting a qubit frequency provided by an embodiment of the present disclosure. Here, the flow 200 includes the following steps.

Step 201 includes determining, according to a fitting corresponding relationship between frequencies of qubits in a multi-bit quantum chip and setting parameters, respective target setting parameters of the qubits at a target frequency, and a corresponding upper-limit setting parameter and a corresponding lower-limit setting parameter of each of the qubits at a frequency range using the target frequency as a center and a preset frequency as a variation limit.

The intention of this step is that, according to the fitting corresponding relationship previously obtained by performing two-dimensional spectral scanning, an executing body (e.g., the computing and control terminal 102 shown in FIG. 1) of the method for adjusting a qubit frequency first determines respective target setting parameters of at least two frequency-adjustable qubits (the qubits mentioned subsequently are all frequency-adjustable qubits) constituting the multi-bit quantum chip at the target frequency, and then further determines the corresponding upper-limit setting parameter of each of the qubits at an upper limit of a frequency range using the target frequency as a center and the preset frequency as a variation limit, and the corresponding lower-limit setting parameter of each of the qubits at a lower limit of the frequency range using the target frequency as a center and the preset frequency as the variation limit.

Here, the fitting corresponding relationship may be obtained by performing two-dimensional spectral scanning on each qubit to obtain a corresponding relationship between the frequency of each qubit and the setting parameter of the frequency regulator and fitting the corresponding relationship, and specifically may be a fitting curve.

Here, the magnitude of the value of the preset frequency is smaller than the magnitude of the target frequency. When the unit of the target frequency is GHz (i.e., 10⁹ hz), the unit of the value of the preset frequency may be MHz (10⁶ hz) that is three orders of magnitude smaller than GHz. At the same time, the value of the preset frequency may be determined and obtained based on the coupling strength between a current qubit and another qubit having a direct coupling relationship with the current qubit. For example, assuming that the target frequency of the current qubit is 4.5 GHz and the coupling strength is 10 MHz, the value of the preset frequency is preferably 28 MHz.

Step 202 includes adjusting, for each qubit, a setting parameter for another qubit having a direct coupling relationship with the qubit to a corresponding upper-limit setting parameter and a corresponding lower-limit setting parameter respectively to obtain a current upper-limit frequency and a current lower-limit frequency of the qubit, after setting respectively setting parameters of a frequency regulator for the qubits to corresponding target setting parameters.

On the basis of step 201, the intention of this step is that the above executing body first sets the setting parameters of the frequency regulator for the qubits to the corresponding target setting parameters, and then adjusts, for each qubit, the setting parameter for another qubit having the direct coupling relationship with the qubit to the corresponding upper-limit setting parameter and the corresponding lower-limit setting parameter respectively, thus obtaining the actual corresponding current upper-limit frequency of each qubit when the upper-limit setting parameter is set and the actual corresponding current lower-limit frequency of each qubit when the lower-limit setting parameter is set.

It should be appreciated that, due to the crosstalk problem among a plurality of qubits at close frequencies, the current upper-limit frequency and the current lower-limit frequency obtained in this step are different from the corresponding upper-limit frequency and the lower-limit frequency determined in step 201 using the same setting parameter.

Step 203 includes calculating a suspected frequency of a corresponding qubit according to the current upper-limit frequency and the current lower-limit frequency.

On the basis of step 202, this step is intended to calculate, by the above executing body, the suspected frequency of the corresponding qubit according to the current upper-limit frequency and the current lower-limit frequency. Specifically, the average value of the current upper-limit frequency and the current lower-limit frequency may be directly used as the suspected frequency of the corresponding qubit. In addition, according to the frequency difference between the current upper-limit frequency and the target frequency and the frequency difference between the current lower-limit frequency and the target frequency, the suspected frequency may be obtained by performing a weight calculation in combination with the different weights of the upper limit and the lower limit, or to calculate the suspected frequency in combination with a preset base value and a preset correction value, which is not specifically limited here as long as the calculated suspected frequency is more in line with actual situations.

Step 204 includes updating, in response to a frequency difference between the suspected frequency and a target frequency of the corresponding qubit being greater than a preset frequency difference, the target setting parameter according to a rate of change between a frequency and a setting parameter that is determined from the fitting corresponding relationship, until a frequency difference between an actual frequency corresponding to an updated setting parameter and the target frequency of the corresponding qubit is not greater than the preset frequency difference.

This step is on the basis that the frequency difference between the suspected frequency determined in step 203 and the target frequency of the corresponding qubit is greater than the preset frequency difference, indicating that there is a large frequency difference between the suspected frequency and the target frequency and the precision requirement that the frequency difference is smaller than the preset frequency difference is not satisfied. Therefore, the target setting parameter may be updated by the above executing body according to the rate of change between the frequency and the setting parameter that is determined from the fitting corresponding relationship, until the frequency difference between the actual frequency corresponding to the updated setting parameter and the target frequency of the corresponding qubit is not greater than the preset frequency difference.

Here, the fitting corresponding relationship represents the corresponding relationships between different frequencies and corresponding setting parameters. Therefore, in combination with the target frequency, the rate between the change of the frequency and the change of the setting parameter when the corresponding qubit is at the target frequency, i.e., a frequency change corresponding to a change of a unit size of a setting parameter, may be acquired according to the fitting curve. Then, in combination with the frequency difference between the suspected frequency and the target frequency of the corresponding qubit, the setting parameter change corresponding to the frequency difference can be determined, and accordingly, the original target setting parameter may be updated using the setting parameter change. Moreover, the purpose of the updating is to make the frequency difference between the actual frequency corresponding to the updated setting parameter and the target frequency of the corresponding qubit not greater than the preset frequency difference. That is, the updating can make the newest frequency difference meet the precision requirement.

Step 205 includes determining that each qubit is in a resonance or near-resonance state, in response to a frequency difference between a suspected frequency and an updated frequency of each qubit being smaller than the preset frequency difference.

This step is after the setting parameter update scheme provided in step 204. After the frequency difference between the suspected frequency and the updated frequency of each qubit is smaller than the preset frequency difference, the above executing body may determine that each qubit is in the resonance or near-resonance state, so as to perform the subsequent quantum operation on the qubit in this state, for example, a quantum operation including quantum walk, optical lattice and Bose-Hubbard model simulations on the multi-bit quantum chip controlled to be in the resonance or near-resonance state, which makes the operation result more accurate and reliable.

According to the method for adjusting a qubit frequency according to the embodiment of the present disclosure, for the at least two frequency-adjustable qubits in the multi-bit quantum chip, the corresponding upper-limit setting parameter and the corresponding lower-limit setting parameter are determined through the upper-limit frequency and the lower-limit frequency which are centered by the target frequency and in combination with the determined fitting corresponding relationship, and thus, the rate between the change of the frequency and the change of the setting parameter may be determined. Then, after the target setting parameter is set for each qubit, for another qubit having the direct coupling relationship with the qubit, the influence of Z-crosstalk on the frequency of the current qubit is determined by adjusting the setting parameter of the another qubit to the upper-limit setting parameter and the lower-limit setting parameter, and then the actual frequency of the current qubit is further precisely determined through the current upper-limit frequency and the current lower-limit frequency. Finally, when the frequency difference between the actual frequency and the target frequency does not meet the precision requirement, the setting parameter is corrected in combination with the rate of change, and accordingly, the actual frequency can be accurately determined, which enables the plurality of qubits on the chip to be practically in the resonance or near-resonance state.

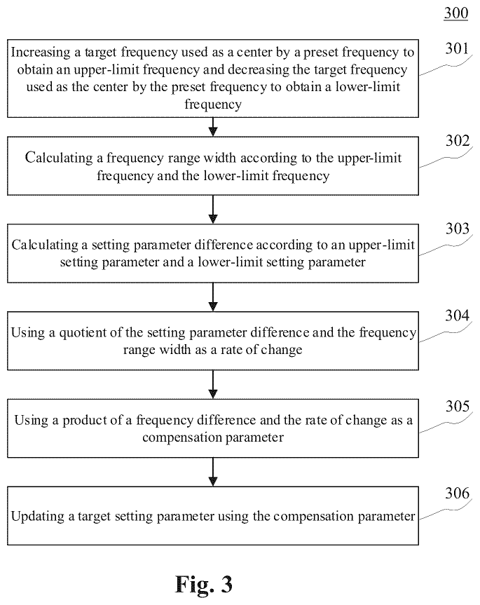

Referring to FIG. 3, FIG. 3 is a flowchart of a method for updating a setting parameter according to a rate of change according to an embodiment of the present disclosure. Here, the flow 300 includes the following steps.

Step 301 includes increasing a target frequency used as a center by a preset frequency, to obtain an upper-limit frequency and decreasing the target frequency used as the center by the preset frequency to obtain a lower-limit frequency.

That is, assuming that the target frequency is X and the preset frequency is Y, the upper-limit frequency is X+Y(GHz), and the lower-limit frequency is X−Y(GHz).

Step 302 includes calculating a frequency range width according to the upper-limit frequency and the lower-limit frequency.

That is, the frequency range width is 2Y.

Step 303 includes calculating a setting parameter difference according to an upper-limit setting parameter and a lower-limit setting parameter.

Assuming that the corresponding upper-limit setting parameter is M1 when the upper-limit frequency is X+Y and the corresponding lower-limit setting parameter is M2 when the lower-limit frequency is X−Y, the setting parameter difference is M1-M2.

Step 304 includes using a quotient of the setting parameter difference and the frequency range width as a rate of change.

That is, the rate of change is

$$\frac{M 1 - M 2}{2 Y} ,$$

that is, a frequency change corresponding to a change of a unit size of the setting parameter.

Step 305 includes using a product of a frequency difference and the rate of change as a compensation parameter.

That is, the compensation parameter is:

$$\frac{M 1 - M 2}{2 Y} \times Δ .$$

Here, A denotes the frequency difference.

Step 306 includes updating a target setting parameter using the compensation parameter.

The way of updating includes: subtracting the target setting parameter by

$$( \frac{M 1 - M 2}{2 Y} \times Δ ) .$$

That is, this embodiment provides, through steps 301-306, a specific implementation scheme of how to update the target setting parameter. First, the rate between the change of the frequency and the change of the setting parameter is calculated according to the fitting corresponding relationship, and then the compensation parameter is calculated in combination with the frequency difference between the suspected frequency and the target frequency, so as to update the target setting parameter in combination with the compensation parameter, such that the updated setting parameter obtained by updating can more accurately adjust frequencies of the corresponding qubit and other qubits to the frequency of the resonance or near-resonance state.

Further, on the basis of the embodiment shown in FIG. 3, the rate of change may be updated in the following way, such that the updated rate of change can more accurately represent the corresponding relationship between the qubit frequency and the setting parameter in an actual situation.

First, a current frequency range width is calculated according to a current upper-limit frequency and a current lower-limit frequency. For example, a difference calculation may be directly performed. The frequency difference between the current upper-limit frequency and the current lower-limit frequency is used as the current frequency range width. It should be understood that the current frequency range width is more accurate than the frequency range width obtained by performing a difference calculation according to the upper-limit frequency and the lower-limit frequency, and then, the rate of change is updated to a quotient of the setting parameter difference and the current frequency range width.

That is, the current frequency range width is more accurate than the frequency range width obtained by performing the difference calculation according to the upper-limit frequency and the lower-limit frequency, and thus, the rate of change calculated therefrom should be more accurate.

On the basis of any of the above embodiments, considering the complexity of the actual situation, the target setting parameter update operation provided in step 204 may be repeatedly performed for multiple times. That is, if the updated setting parameter obtained by one update is still unable to make the frequency difference between the corresponding actual frequency and the target frequency not greater than a preset frequency difference, the update operation may be performed again based on a current updated setting parameter, until the frequency difference between the actual frequency corresponding to the updated setting parameter and the target frequency of the corresponding qubit is not greater than the preset frequency difference or the number of update operations exceeds a preset number, so as to avoid the waste of computing power caused by the situation that after multiple rounds of adjustment the frequency is still unable to make the frequency difference meet the precision requirement.

For a deeper understanding, the present disclosure further gives a specific implementation in combination with a specific application scenario.

In step 1, for each qubit in a multi-bit quantum chip, a large-range frequency modulation curve of a qubit i (the range of which is 1-N) is measured by performing two-dimensional spectral scanning, for fitting to obtain a corresponding relationship between the frequency of the qubit i and a setting parameter of a frequency regulator. The value Zᵢ of the setting parameter of the frequency regulator for the qubit when the frequency is a specified frequency ωᵢ and the values Z of the corresponding setting parameters when the frequency is ωⱼ±2.8 g (the specified frequency ωᵢ increases or decreases by 2.8 g) are obtained through the fitting curve, and at the same time, the rate Rᵢ between the change of the frequency of the qubit and the change of the setting parameter Zᵢ when the frequency is at the specified frequency ωᵢ is calculated.

In step 2, step 1 is repeated for each of the first to Nₜₕ qubits, where N is the number of frequency-adjustable qubits included in the multi-bit quantum chip.

Step 3, the setting parameters of the frequency regulator for all the qubits are set to the setting parameter {Zᵢ} that is recorded in above steps. Due to the influence of the frequency regulation crosstalk between the qubits, each of the qubits is at a frequency close to a respective specified frequency, which is denoted as ωᵢ^{nr}, where nr is an abbreviation for near resonance.

In step 4, the frequencies of all qubits {j} having a direct coupling relationship with the qubit i are respectively regulated to Zᵢ^{±}, and a measurement is performed again to obtain a current frequency ωᵢ^{±}to of the qubit i, and accordingly,

$${ω}_{i}^{n r} = \frac{( {ω}_{i}^{+} + {ω}_{i}^{-} )}{2}$$

can be obtained.

In step 5, there is a frequency difference Δ=ωᵢ^{nr}−ωᵢ between ωᵢ^{nr} and the specified frequency ωᵢ. Through the rate Rᵢ of change of the frequency of the qubit and the change of the setting parameter Zᵢ, it can be calculated that Zᵢ needs to be finely regulated to Zᵢ−Δ/Rᵢ; if there is a need for a compensation of Δ. That is, the parameter of the frequency regulator is actually required to be set to Zᵢ−Δ/Rᵢ; if a frequency of the qubit i in a near-resonance state needs to be regulated to the frequency ωᵢ. The parameter ZᵢΔ/Rᵢ is recorded as n, where the superscript 1 indicates the result of the first round of optimization.

In step 6, steps 4 and 5 are repeated for all the qubits, thus obtaining a set of new parameters {Zᵢ¹}

In step 7, steps 4, 5 and 6 may be repeated for multiple rounds of optimization.

That is, in the above scheme, the near-resonance frequency conn of the qubit is precisely determined through step 4, and then the deviation caused by the crosstalk is corrected through step 5, thus making the setting precision greatly improved.

For ease of understanding, the principle of calibrating the near-resonance frequency ωᵢ^{nr} of the qubit in step 4 is introduced as follows. Taking two qubits as an example, the Hamiltonian of the two qubits is considered as a fixed coupling form:

$$H = \frac{{ω}_{1}}{2} {σ}_{1}^{z} + \frac{{ω}_{2}}{2} {σ}_{2}^{z} + g ( {σ}_{1}^{+} {σ}_{2}^{-} + {σ}_{1}^{-} {σ}_{2}^{+} ) ,$$

it may be solved that an energy-level eigenvalue is:

$${E}_{1} = \frac{{ω}_{1} + {ω}_{2}}{2} + \frac{1}{2} \sqrt{{( {ω}_{1} - {ω}_{2} )}^{2} + 4 {g}^{2}} , \\ {E}_{2} = \frac{{ω}_{1} + {ω}_{2}}{2} - \frac{1}{2} \sqrt{{( {ω}_{1} - {ω}_{2} )}^{2} + 4 {g}^{2}} .$$

If the qubits are in a resonance state (i.e., ω₁=ω₂), E₁=ω₁+g and E₂=ω₁−g. In this case, double peaks symmetrical about a center frequency are formed on an energy spectrum.

In combination with the numerical simulation of a two-dimensional spectral scanning process on two qubits that are resonant, it can be seen that, the numerical result of a dynamics excitation (spectral scanning) process on one qubit that is in a near-resonance region only appears at one point of the theoretical symmetrical double peaks, and when the frequency difference reaches a certain extent, the double peaks are obviously suppressed, but there is still a frequency repulsion.

This double-peak suppression process may be quantitatively discussed through the following method.

When the two qubits are coupled, spectral scanning is performed on one of the qubits, of which the probability should have the following form:

$${P}_{1} = \frac{4 {g}^{2}}{4 {g}^{2} + {( Δ - \sqrt{{Δ}^{2} + 4 {g}^{2}} )}^{2}} .$$

Here, Δ=(ω₁−ω₂). As previously described, two symmetrical peaks are formed when the qubits resonate. In this case, the probability of each of the two qubits being in the 1 state is ½. It may be considered that the desired double-peak suppression effect is achieved when one peak is more than ten times higher than the other peak, and thus,

$$\frac{4 {g}^{2}}{4 {g}^{2} + {( Δ - \sqrt{{Δ}^{2} + 4 {g}^{2}} )}^{2}} \geq 10 \times ( 1 - \frac{4 {g}^{2}}{4 {g}^{2} + {( Δ - \sqrt{{Δ}^{2} + 4 {g}^{2}} )}^{2}} ) .$$

Accordingly, it may be solved that

$$Δ \geq \frac{9}{1 O} \sqrt{10} g or Δ \leq - \frac{9}{10} \sqrt{10} g .$$

Therefore, the double-peak suppression effect may be achieved merely by selecting a range of Δ>2.8 g. Another problem needing to be considered is the size of the frequency deviation and the minimum frequency that can be resolved experimentally. When Δ is positive and has a large range, the frequency offset is very small:

$${E}_{1} = \frac{{ω}_{1} + {ω}_{1} - Δ}{2} + \frac{1}{2} \sqrt{{Δ}^{2} + 4 {g}^{2}} \approx {ω}_{1} + \frac{{g}^{2}}{Δ} .$$

Experimentally, the precision of the spectral scanning experiment depends on the minimum step size and the fitting approach. 0.05 MHz may be used as the lower limit, and accordingly,

$$\frac{{g}^{2}}{Δ} \geq 0.05 MHz .$$

The method according to this embodiment is performed in the near-resonance region, and general experimental data is substituted into the above formulas. Assuming that the qubit A and the qubit B are desired to resonate at 4.5 GHz, their coupling strength is 10 MHz. Accordingly, it may be concluded from the above discussion that the width of the near-resonance region is 2.8 g≤Δ≤14 g.

In order to obtain the best precision, the lower limit Δ=28 MHz is selected. First, the frequency of qubit B is adjusted to 4.5 GHz through the data of a two-dimensional energy spectrum, and then the frequency of qubit A is adjusted through the two-dimensional energy spectrum to a frequency above the qubit B by 100 MHz, that is, 4.6 GHz. In this case, by scanning the energy spectrum of the qubit B, it may be obtained that:

$${ω}_{B}^{+} = \frac{{ω}_{B} + {ω}_{B} + 0.028}{2} - \frac{1}{2} \sqrt{{( 0.28 )}^{2} + 4 {g}^{2}} .$$

Then, the frequency of the qubit A is adjusted to be below the qubit B by 100 M, that is, 4.4 GHz. In this case, by scanning the energy spectrum of the qubit B, it may be obtained that:

$${ω}_{B}^{-} = \frac{{ω}_{B} + {ω}_{B} - 0.028}{2} + \frac{1}{2} \sqrt{{( 028 )}^{2} + 4 {g}^{2}} .$$

Through ω_{B}⁺and ω_{B}⁻, it is obtained that

$${ω}_{B} = \frac{{ω}_{B}^{-} + {ω}_{B}^{+}}{2} .$$

The frequency at which the qubits B and A (nearly) resonate may be precisely measured and calibrated experimentally in this way, and the precision of 0.1 MHz or less may generally be achieved experimentally by only two iterations.

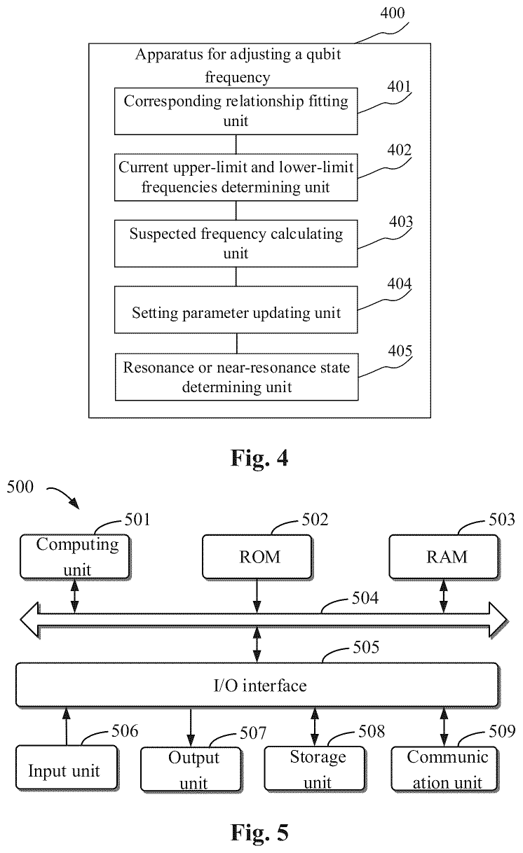

Further referring to FIG. 4, as an implementation of the method shown in the above drawings, the present disclosure provides an embodiment of an apparatus for adjusting a qubit frequency. The embodiment of the apparatus corresponds to the embodiment of the method shown in FIG. 2, and the apparatus may be applied in various electronic devices.

As shown in FIG. 4, an apparatus 400 for adjusting a qubit frequency in this embodiment includes: a corresponding relationship fitting unit 401, a current upper-limit and lower-limit frequencies determining unit 402, a suspected frequency calculating unit 403, a setting parameter updating unit 404 and a resonance or near-resonance state determining unit 405. Here, the corresponding relationship fitting unit 401 is configured to determine, according to a fitting corresponding relationship between frequencies of at least two frequency-adjustable qubits in a multi-bit quantum chip and setting parameters, respective target setting parameters of the qubits at a target frequency, a corresponding upper-limit setting parameter and a corresponding lower-limit setting parameter of each of the qubits at a frequency range using the target frequency as a center and a preset frequency as a variation limit. The current upper-limit and lower-limit frequencies determining unit 402 is configured to adjust, for each qubit, a setting parameter for another qubit having a direct coupling relationship with the qubit to a corresponding upper-limit setting parameter and a corresponding lower-limit setting parameter respectively to obtain a current upper-limit frequency and a current lower-limit frequency of the qubit, after setting respectively setting parameters of a frequency regulator for the qubits to corresponding target setting parameters. The suspected frequency calculating unit 403 is configured to calculate a suspected frequency of a corresponding qubit according to the current upper-limit frequency and the current lower-limit frequency. The setting parameter updating unit 404 is configured to update, in response to a frequency difference between the suspected frequency and a target frequency of the corresponding qubit being greater than a preset frequency difference, the target setting parameter according to a rate of change between a frequency and a setting parameter that is determined from the fitting corresponding relationship, until a frequency difference between an actual frequency corresponding to an updated setting parameter and the target frequency of the corresponding qubit is not greater than the preset frequency difference. The resonance or near-resonance state determining unit 405 is configured to determine that each qubit is in a resonance or near-resonance state, in response to a frequency difference between a suspected frequency and an updated frequency of each qubit being smaller than the preset frequency difference.

In this embodiment, for specific processes of the corresponding relationship fitting unit 401, the current upper-limit and lower-limit frequencies determining unit 402, the suspected frequency calculating unit 403, the setting parameter updating unit 404 and the resonance or near-resonance state determining unit 405 in the apparatus 400 for adjusting a qubit frequency, and their technical effects, reference may be respectively made to the related descriptions of steps 201-205 in the corresponding embodiment of FIG. 2, and thus, the details will not be repeatedly described here.

In some alternative implementations of this embodiment, the suspected frequency calculating unit 403 may be further configured to:

use an average value of the current upper-limit frequency and the current lower-limit frequency as the suspected frequency of the corresponding qubit.

In some alternative implementations of this embodiment, the apparatus 400 for adjusting a qubit frequency may further include:

a two-dimensional spectral scanning unit, configured to perform two-dimensional spectral scanning on each qubit in the multi-bit quantum chip to obtain a fitting corresponding relationship between a frequency of each qubit and a setting parameter of the frequency regulator.

In some alternative implementations of this embodiment, the setting parameter updating unit 404 may be further configured to:

increasing a target frequency used as a center by a preset frequency, to obtain an upper-limit frequency and decreasing the target frequency used as the center by the preset frequency to obtain a lower-limit frequency;

calculate a frequency range width according to the upper-limit frequency and the lower-limit frequency;

calculate a setting parameter difference according to the upper-limit setting parameter and the lower-limit setting parameter;

use a quotient of the setting parameter difference and the frequency range width as the rate of change;

use a product of a frequency difference and the rate of change as a compensation parameter; and

update the target setting parameter using the compensation parameter.

In some alternative implementations of this embodiment, the apparatus 400 for adjusting a qubit frequency may further include:

a current frequency range width calculating unit, configured to calculate a current frequency range width according to the current upper-limit frequency and the current lower-limit frequency; and

a rate-of-change updating unit, configured to update the rate of change to a quotient of the setting parameter difference and the current frequency range width.

In some alternative implementations of this embodiment, the apparatus 400 for adjusting a qubit frequency may further include:

a multi-round updating unit, configured to perform, in response to an updated

setting parameter obtained by one update being still unable to make a frequency difference between a corresponding actual frequency and the target frequency not greater than the preset frequency difference, an update operation again based on a current updated setting parameter, until the frequency difference between the actual frequency corresponding to the updated setting parameter and the target frequency of the corresponding qubit is not greater than the preset frequency difference or a number of update operations exceeds a preset number.

In some alternative implementations of this embodiment, a magnitude of the value of the preset frequency is smaller than a magnitude of the target frequency, and the value of the preset frequency is determined and obtained based on a coupling strength for direct coupling.

In some alternative implementations of this embodiment, the apparatus 400 for adjusting a qubit frequency may further include:

a quantum operation performing unit, configured to perform a quantum operation including quantum walk, optical lattice and Bose-Hubbard model simulations on a multi-bit quantum chip controlled to be in a resonance or near-resonance state.

This embodiment is an apparatus embodiment corresponding to the above method embodiment. According to the apparatus for adjusting a qubit frequency provided in this embodiment, for the at least two frequency-adjustable qubits in the multi-bit quantum chip, the corresponding upper-limit setting parameter and the corresponding lower-limit setting parameter are determined through the upper-limit frequency and the lower-limit frequency that which are centered by the target frequency and in combination with the determined fitting corresponding relationship, and thus, the rate between the change of the frequency and the change of the setting parameter may be determined. Then, after the target setting parameter is set for each qubit, for another qubit having the direct coupling relationship with the qubit, the influence of Z-crosstalk on the frequency of the current qubit is determined by adjusting the setting parameter of the another qubit to the upper-limit setting parameter and the lower-limit setting parameter, and then the actual frequency of the current qubit is further precisely determined through the current upper-limit frequency and the current lower-limit frequency. Finally, when the frequency difference between the actual frequency and the target frequency does not meet the precision requirement, the setting parameter is corrected in combination with the rate of change, and accordingly, the actual frequency can be accurately determined, which enables the plurality of qubits on the chip to be practically in the resonance or near-resonance state.

According to an embodiment of the present disclosure, the present disclosure further provides an electronic device. The electronic device includes at least one processor, and a memory in communication with the at least one processor. Here, the memory stores instructions executable by the at least one processor, and the instructions are executed by the at least one processor, to enable the at least one processor to implement the method for adjusting a qubit frequency described in any of the above embodiments.

According to an embodiment of the present disclosure, the present disclosure further provides a readable storage medium. The readable storage medium stores one or more computer instructions. Here, the one or more computer instructions are used to enable a computer to implement the method for adjusting a qubit frequency described in any of the above embodiments.

According to an embodiment of the present disclosure, the present disclosure further provides a computer program product. The computer program, when executed by a processor, can implement the steps of the method for adjusting a qubit frequency described in any of the above embodiments.

FIG. 5 is a schematic block diagram of an example electronic device 500 that may be used to implement the embodiments of the present disclosure. The electronic device is intended to represent various forms of digital computers such as a laptop computer, a desktop computer, a workstation, a personal digital assistant, a server, a blade server, a mainframe computer, and other appropriate computers. The electronic device may alternatively represent various forms of mobile apparatuses such as personal digital assistant, a cellular telephone, a smart phone, a wearable device and other similar computing apparatuses. The parts shown herein, their connections and relationships, and their functions are only as examples, and not intended to limit implementations of the present disclosure as described and/or claimed herein.

As shown in FIG. 5, the device 500 includes a computation unit 501, which may perform various appropriate actions and processing, based on a computer program stored in a read-only memory (ROM) 502 or a computer program loaded from a storage unit 508 into a random access memory (RAM) 503. In the RAM 503, various programs and data required for the operation of the device 500 may also be stored. The computation unit 501, the ROM 502, and the RAM 503 are connected to each other through a bus 504. An input/output (I/O) interface 505 is also connected to the bus 504.

A plurality of parts in the device 500 are connected to the I/O interface 505, including: an input unit 506, for example, a keyboard and a mouse; an output unit 507, for example, various types of displays and speakers; the storage unit 508, for example, a disk and an optical disk; and a communication unit 509, for example, a network card, a modem, or a wireless communication transceiver. The communication unit 509 allows the device 500 to exchange information/data with other devices over a computer network such as the Internet and/or various telecommunication networks.

The computation unit 501 may be various general-purpose and/or dedicated processing components having processing and computing capabilities. Some examples of the computation unit 501 include, but are not limited to, central processing unit (CPU), graphics processing unit (GPU), various dedicated artificial intelligence (AI) computing chips, various computation units running machine learning model algorithms, digital signal processors (DSP), and any appropriate processors, controllers, microcontrollers, etc. The computation unit 501 performs the various methods and processes described above, such as the method for adjusting a frequency of a qubit. For example, in some embodiments, the method for adjusting a frequency of a qubit may be implemented as a computer software program, which is tangibly included in a machine readable medium, such as the storage unit 508. In some embodiments, part or all of the computer program may be loaded and/or installed on the device 500 via the ROM 502 and/or the communication unit 509. When the computer program is loaded into the RAM 503 and executed by the computation unit 501, one or more steps of the method for adjusting a frequency of a qubit may be performed. Alternatively, in other embodiments, the computation unit 501 may be configured to perform the method for adjusting a frequency of a qubit by any other appropriate means (for example, by means of firmware).

Various embodiments of the systems and technologies described above can be implemented in digital electronic circuit system, integrated circuit system, field programmable gate array (FPGA), application specific integrated circuit (ASIC), application special standard product (ASSP), system on chip (SOC), complex programmable logic device (CPLD), computer hardware, firmware, software, and/or combinations thereof. These various embodiments may include being implemented in one or more computer programs that may be executed and/or interpreted on a programmable system including at least one programmable processor, which may be a dedicated or general programmable processor that may receive data and instructions from a storage system, at least one input device, and at least one output device, and transmit data and instructions to the storage system, the at least one input device, and the at least one output device.

Program codes for implementing the method of the present disclosure may be written in any combination of one or more programming languages. These program codes may be provided to a processor or controller of a general purpose computer, special purpose computer or other programmable apparatus for data processing such that the program codes, when executed by the processor or controller, enables the functions/operations specified in the flowcharts and/or block diagrams being implemented. The program codes may execute entirely on the machine, partly on the machine, as a stand-alone software package partly on the machine and partly on the remote machine, or entirely on the remote machine or server.

In the context of the present disclosure, the machine readable medium may be a tangible medium that may contain or store programs for use by or in connection with an instruction execution system, apparatus, or device. The machine readable medium may be a machine readable signal medium or a machine readable storage medium. The machine readable medium may include, but is not limited to, an electronic, magnetic, optical, electromagnetic, infrared, or semiconductor system, apparatus, or device, or any suitable combination of the foregoing. More specific examples of the machine readable storage medium may include an electrical connection based on one or more wires, portable computer disk, hard disk, random access memory (RAM), read only memory (ROM), erasable programmable read only memory (EPROM or flash memory), optical fiber, portable compact disk read only memory (CD-ROM), optical storage device, magnetic storage device, or any suitable combination of the foregoing.

In order to provide interaction with the user, the systems and techniques described herein may be implemented on a computer having: a display device for displaying information to the user (e.g., a CRT (cathode ray tube) or LCD (liquid crystal display) monitor); a keyboard and a pointing device (e.g., mouse or trackball), through which the user can provide input to the computer. Other kinds of devices can also be used to provide interaction with users. For example, the feedback provided to the user may be any form of sensory feedback (e.g., visual feedback, auditory feedback, or tactile feedback); and the input from the user can be received in any form (including acoustic input, voice input or tactile input).

The systems and technologies described herein may be implemented in a computing system that includes a back-end component (e.g., as a data server), or a computing system that includes a middleware component (e.g., an application server), or a computing system that includes a front-end component (e.g., a user computer with a graphical user interface or a web browser through which the user can interact with an implementation of the systems and technologies described herein), or a computing system that includes any combination of such a back-end component, such a middleware component, or such a front-end component. The components of the system may be interconnected by digital data communication (e.g., a communication network) in any form or medium. Examples of the communication network include: a local area network (LAN), a wide area network (WAN), and the Internet.

The computer system may include a client and a server. The client and the server are generally remote from each other, and generally interact with each other through a communication network. The relationship between the client and the server is generated by virtue of computer programs that run on corresponding computers and have a client-server relationship with each other. The server may be a cloud server, which is also known as a cloud computing server or a cloud host, and is a host product in a cloud computing service system to solve the defects of difficult management and weak service extendibility existing in conventional physical hosts and virtual private servers (VPS).

According to the technical solution of the embodiments of the present disclosure, for each qubit constituting a multi-bit quantum chip, a corresponding upper-limit setting parameter and a corresponding lower-limit setting parameter are determined through an upper-limit frequency and a lower-limit frequency which are centered by a target frequency and in combination with a determined fitting corresponding relationship, and thus, a rate of change between a frequency and the change of a setting parameter may be determined. Then, after the target setting parameter is set for each qubit, for another qubit having a direct coupling relationship with the qubit, the influence of Z-crosstalk on the frequency of a current qubit is determined by adjusting the setting parameter of the another qubit to the upper-limit setting parameter and the lower-limit setting parameter, and then the actual frequency of the current qubit is further precisely determined through a current upper-limit frequency and a current lower-limit frequency. Finally, when the frequency difference between the actual frequency and the target frequency does not meet a precision requirement, the setting parameter is corrected in combination with the rate of change, and accordingly, the actual frequency can be accurately determined, which enables the plurality of qubits on the chip to be practically in a resonance or near-resonance state.

It should be understood that the various forms of processes shown above may be used to reorder, add, or delete steps. For example, the steps disclosed in the present disclosure may be executed in parallel, sequentially, or in different orders, as long as the desired results of the technical solutions mentioned in the present disclosure can be implemented. This is not limited herein.

The above specific embodiments do not constitute any limitation to the scope of protection of the present disclosure. It should be understood by those skilled in the art that various modifications, combinations, sub-combinations, and replacements may be made according to the design requirements and other factors. Any modification, equivalent replacement, improvement, and the like made within the spirit and principle of the present disclosure should be encompassed within the scope of protection of the present disclosure.

What is claimed is:

1. A method for adjusting a qubit frequency, comprising:
determining, according to fitting corresponding relationships between frequencies of at least two frequency-adjustable qubits in a multi-bit quantum chip and setting parameters, respective target setting parameters of the qubits at a target frequency, and a corresponding upper-limit setting parameter and a corresponding lower-limit setting parameter of each of the qubits at a frequency range using the target frequency as a center and a preset frequency as a variation limit;
adjusting, for each qubit, a setting parameter for another qubit having a direct coupling relationship with the each qubit to a corresponding upper-limit setting parameter and a corresponding lower-limit setting parameter respectively to obtain a current upper-limit frequency and a current lower-limit frequency of the each qubit, after setting respectively setting parameters of a frequency regulator for the qubits to corresponding target setting parameters;
calculating a suspected frequency of a corresponding qubit according to the current upper-limit frequency and the current lower-limit frequency;
updating, in response to a frequency difference between the suspected frequency and a target frequency of the corresponding qubit being greater than a preset frequency difference, the target setting parameter according to a rate of change between a frequency and a setting parameter until a frequency difference between an actual frequency corresponding to an updated setting parameter and the target frequency of the corresponding qubit is not greater than the preset frequency difference, the rate of change being determined from the fitting corresponding relationship; and
determining that each qubit is in a resonance or near-resonance state, in response to a frequency difference between a suspected frequency and an updated frequency of the each qubit being smaller than the preset frequency difference.

2. The method according to claim 1, wherein the calculating the suspected frequency of the corresponding qubit according to the current upper-limit frequency and the current lower-limit frequency comprises:
using an average value of the current upper-limit frequency and the current lower-limit frequency as the suspected frequency of the corresponding qubit.

3. The method according to claim 1, further comprising:
performing two-dimensional spectral scanning on each qubit in the multi-bit quantum chip to obtain the fitting corresponding relationship between the frequency of the each qubit and the setting parameter of the frequency regulator.

4. The method according to claim 1, wherein updating the target setting parameter according to the rate of change between the frequency and the setting parameter comprises:
increasing the target frequency used as the center by the preset frequency, to obtain an upper-limit frequency, and decreasing the target frequency used as the center by the preset frequency to obtain a lower-limit frequency;
calculating a frequency range width according to the upper-limit frequency and the lower-limit frequency;
calculating a setting parameter difference according to the upper-limit setting parameter and the lower-limit setting parameter;
using a quotient of the setting parameter difference and the frequency range width as the rate of change;
using a product of a frequency difference and the rate of change as a compensation parameter; and
updating the target setting parameter using the compensation parameter.

5. The method according to claim 4, further comprising:
calculating a current frequency range width according to the current upper-limit frequency and the current lower-limit frequency; and
updating the rate of change to a quotient of the setting parameter difference and the current frequency range width.

6. The method according to claim 1, further comprising:
performing, in response to an updated setting parameter obtained by one update being still unable to make a frequency difference between a corresponding actual frequency and the target frequency not greater than the preset frequency difference, an update operation again based on a current updated setting parameter until the frequency difference between the actual frequency corresponding to the updated setting parameter and the target frequency of the corresponding qubit is not greater than the preset frequency difference or a number of update operations exceeds a preset number.

7. The method according to claim 1, wherein a magnitude of the preset frequency is smaller than a magnitude of the target frequency, and the preset frequency is determined and obtained based on a coupling strength for direct coupling.

8. The method according to claim 1, further comprising:
performing a quantum operation comprising quantum walk, optical lattice and Bose-Hubbard model simulations on the multi-bit quantum chip controlled to be in a resonance or near-resonance state.

9. An electronic device, comprising:
at least one processor; and
a memory in communication with the at least one processor,
wherein the memory stores instructions executable by the at least one processor, and the instructions, when executed by the at least one processor, cause the at least one processor to perform operations comprising:
determining, according to fitting corresponding relationships between frequencies of at least two frequency-adjustable qubits in a multi-bit quantum chip and setting parameters, respective target setting parameters of the qubits at a target frequency, and a corresponding upper-limit setting parameter and a corresponding lower-limit setting parameter of each of the qubits at a frequency range using the target frequency as a center and a preset frequency as a variation limit;
adjusting, for each qubit, a setting parameter for another qubit having a direct coupling relationship with the each qubit to a corresponding upper-limit setting parameter and a corresponding lower-limit setting parameter respectively to obtain a current upper-limit frequency and a current lower-limit frequency of the each qubit, after setting respectively setting parameters of a frequency regulator for the qubits to corresponding target setting parameters;
calculating a suspected frequency of a corresponding qubit according to the current upper-limit frequency and the current lower-limit frequency;
updating, in response to a frequency difference between the suspected frequency and a target frequency of the corresponding qubit being greater than a preset frequency difference, the target setting parameter according to a rate of change between a frequency and a setting parameter until a frequency difference between an actual frequency corresponding to an updated setting parameter and the target frequency of the corresponding qubit is not greater than the preset frequency difference, the rate of change being determined from the fitting corresponding relationship; and
determining that each qubit is in a resonance or near-resonance state, in response to a frequency difference between a suspected frequency and an updated frequency of the each qubit being smaller than the preset frequency difference.

10. The electronic device according to claim 9, wherein the calculating the suspected frequency of the corresponding qubit according to the current upper-limit frequency and the current lower-limit frequency comprises:
using an average value of the current upper-limit frequency and the current lower-limit frequency as the suspected frequency of the corresponding qubit.

11. The electronic device according to claim 9, wherein the operations further comprise:
performing two-dimensional spectral scanning on each qubit in the multi-bit quantum chip to obtain the fitting corresponding relationship between the frequency of the each qubit and the setting parameter of the frequency regulator.

12. The electronic device according to claim 9, wherein updating the target setting parameter according to the rate of change between the frequency and the setting parameter comprises:
increasing the target frequency used as the center by the preset frequency, to obtain an upper-limit frequency, and decreasing the target frequency used as the center by the preset frequency to obtain a lower-limit frequency;
calculating a frequency range width according to the upper-limit frequency and the lower-limit frequency;
calculating a setting parameter difference according to the upper-limit setting parameter and the lower-limit setting parameter;
using a quotient of the setting parameter difference and the frequency range width as the rate of change;
using a product of a frequency difference and the rate of change as a compensation parameter; and
updating the target setting parameter using the compensation parameter.

13. The electronic device according to claim 12, wherein the operations further comprise:
calculating a current frequency range width according to the current upper-limit frequency and the current lower-limit frequency; and
updating the rate of change to a quotient of the setting parameter difference and the current frequency range width.

14. The electronic device according to claim 9, wherein the operations further comprise:
performing, in response to an updated setting parameter obtained by one update being still unable to make a frequency difference between a corresponding actual frequency and the target frequency not greater than the preset frequency difference, an update operation again based on a current updated setting parameter until the frequency difference between the actual frequency corresponding to the updated setting parameter and the target frequency of the corresponding qubit is not greater than the preset frequency difference or a number of update operations exceeds a preset number.

15. The electronic device according to claim 9, wherein a magnitude of the preset frequency is smaller than a magnitude of the target frequency, and the preset frequency is determined and obtained based on a coupling strength for direct coupling.

16. The electronic device according to claim 9, wherein the operations further comprise:
performing a quantum operation comprising quantum walk, optical lattice and Bose-Hubbard model simulations on the multi-bit quantum chip controlled to be in a resonance or near-resonance state.

17. A non-transitory computer readable storage medium, storing computer instructions that, when executed by a computer, cause the computer to perform operations comprising:
determining, according to fitting corresponding relationships between frequencies of at least two frequency-adjustable qubits in a multi-bit quantum chip and setting parameters, respective target setting parameters of the qubits at a target frequency, and a corresponding upper-limit setting parameter and a corresponding lower-limit setting parameter of each of the qubits at a frequency range using the target frequency as a center and a preset frequency as a variation limit;
adjusting, for each qubit, a setting parameter for another qubit having a direct coupling relationship with the each qubit to a corresponding upper-limit setting parameter and a corresponding lower-limit setting parameter respectively to obtain a current upper-limit frequency and a current lower-limit frequency of the each qubit, after setting respectively setting parameters of a frequency regulator for the qubits to corresponding target setting parameters;
calculating a suspected frequency of a corresponding qubit according to the current upper-limit frequency and the current lower-limit frequency;
updating, in response to a frequency difference between the suspected frequency and a target frequency of the corresponding qubit being greater than a preset frequency difference, the target setting parameter according to a rate of change between a frequency and a setting parameter until a frequency difference between an actual frequency corresponding to an updated setting parameter and the target frequency of the corresponding qubit is not greater than the preset frequency difference, the rate of change being determined from the fitting corresponding relationship; and
determining that each qubit is in a resonance or near-resonance state, in response to a frequency difference between a suspected frequency and an updated frequency of the each qubit being smaller than the preset frequency difference.

18. The computer readable storage medium according to claim 17, wherein the calculating the suspected frequency of the corresponding qubit according to the current upper-limit frequency and the current lower-limit frequency comprises:
using an average value of the current upper-limit frequency and the current lower-limit frequency as the suspected frequency of the corresponding qubit.

19. The computer readable storage medium according to claim 17, wherein the operations further comprise:
performing two-dimensional spectral scanning on each qubit in the multi-bit quantum chip to obtain the fitting corresponding relationship between the frequency of the each qubit and the setting parameter of the frequency regulator.

20. The computer readable storage medium according to claim 17, wherein updating the target setting parameter according to the rate of change between the frequency and the setting parameter comprises:
increasing the target frequency used as the center by the preset frequency, to obtain an upper-limit frequency, and decreasing the target frequency used as the center by the preset frequency to obtain a lower-limit frequency;
calculating a frequency range width according to the upper-limit frequency and the lower-limit frequency;
calculating a setting parameter difference according to the upper-limit setting parameter and the lower-limit setting parameter;
using a quotient of the setting parameter difference and the frequency range width as the rate of change;
using a product of a frequency difference and the rate of change as a compensation parameter; and
updating the target setting parameter using the compensation parameter.
